(19) United States
(12) Patent Application Publication
(10) Pub. No.: US 2026/0150302 A1
(43) Pub. Date: May 28, 2026

(54) HYBRID BONDING STRUCTURE AND MACHINE LEANING ACCELERATOR

(71) Applicants: SK hynix Inc., Icheon-si (KR); SEOUL NATIONAL UNIVERSITY R&DB FOUNDATION, Seoul (KR)

(72) Inventors: Byung Kuk YOON, Icheon-si (KR); Choung Ki SONG, Icheon-si (KR); Jae Joon KIM, Seoul (KR); Sang Hyeok HAN, Seoul (KR)

(21) Appl. No.: 19/076,854

(22) Filed: Mar. 11, 2025

(30) Foreign Application Priority Data
Nov. 28, 2024 (KR) 10-2024-0173317

(51) Int. Cl. H10B 80/00; G06F 7/544; H01L 23/00; H01L 25/065; H01L 25/18

(52) U.S. Cl. CPC H10B 80/00; G06F 7/5443; H10W 90/00; H10W 90/792

(57) ABSTRACT

A hybrid bonding structure includes a local transmission line and a global transmission line each connecting a memory chip to a logic chip. During a read operation, data is directly transmitted from the memory chip to the logic chip through the local transmission line. During a write operation, data is transmitted from the logic chip to the memory chip through the global transmission line. A control signal is transmitted from the logic chip to the memory chip through the global transmission line. Accordingly, a plurality of banks implemented in the memory chip can be simultaneously controlled and a plurality of Processor Element s (Pes) implemented in the logic chip may operate as a single core. The hybrid bonding structure may be used to implement a machine learning accelerator.

### CROSS-REFERENCE TO RELATED APPLICATION

This application claims priority under 35 U.S.C. § 119 to Korean Patent Application No. 10-2024-0173317 filed on Nov. 28, 2024, which is incorporated herein by reference in its entirety.

### BACKGROUND

### 1. Field

Illustrative embodiments relate to a hybrid bonding structure, and particularly, to a hybrid bonding structure in which data is directly transmitted from a memory chip to a logic chip through a local transmission line during a read operation, data is transmitted from the logic chip to the memory chip through a global transmission line during a write operation, and a control signal is transmitted from the logic chip to the memory chip through the global transmission line, so that a plurality of banks can be simultaneously controlled and a plurality of PEs implemented in the logic chip operate as a single core. Illustrative embodiments also relate to a machine leaning accelerator including such a hybrid bonding structure.

### 2. Discussion of the Related Art

FIG. 1 illustrates a Dynamic Random Access Memory (DRAM) having a plurality of banks in the related art.

Referring to FIG. 1, a plurality of banks included in a DRAM in the related art are connected to a host located outside the DRAM by using an internal bus Data bus and an off-chip interface that are shared by the banks. Since the structure in the related art in which the DRAM is connected to the host operates by a shared bus Data bus inside the DRAM, there is a disadvantage in that the bandwidth of a signal for each bank is limited.

In order to solve such a problem, various multi-stacked elements that form a single structure (i.e. a multi-stacked device) by stacking a plurality of semiconductor elements are being studied. For example, semiconductor elements that implement image sensors, logic elements, and memories may be stacked to form one structure.

In the multi-stacked device, the semiconductor elements that are stacked need be electrically connected to each other, and to achieve this, a process using a through silicon via (TSV) structure being a 3D stack technology has been proposed and used.

The TSV is a technology that electrically connects upper and lower functional blocks that are stacked by drilling a fine hole (i.e., a Via) in a chip on a wafer. This is a commercialized technology for implementing a large-capacity memory device by stacking memory dies. The TSV can significantly increase speed and reduce power consumption compared to a wire bonding technology in the related art, but has the disadvantage of increasing a consumption of area on the chips.

A hybrid bonding (HB) technology, which has been proposed as a technology that can reduce power consumption and consumption area compared to the TSV technology, connects, for example, a memory chip and a logic chip that are designed/manufactured in different processes and stacked with copper bonding. In HB, the memory chip and the logic chip may each have a top layer having connection pads disposed thereon, and the two chips are disposed with the top layers facing each other and then processed to create an electrical connection between the connection pads on the two chip.

FIG. 2 illustrates an example of a hybrid bonding structure in the related art.

Referring to FIG. 2, a hybrid bonding structure 200 in the related art connects, by using a hybrid bonding method, a memory chip 210 including a plurality of banks and a logic chip 250 including a plurality of pairs each comprising a processing element PE and a controller Ctrl that together may perform, for example, a multiply accumulation (MAC) operation.

In FIG. 2, it can be seen that a connection line indicated by a solid double-headed arrow transmits and receives data between a bank Bank and a corresponding controller Ctrl, and a connection line indicated by a dotted single-headed arrow transmits a control signal from the controller Ctrl to the corresponding bank Bank. In addition, control signals CMD and ADDR transmitted from a host Host to each controller Ctrl are indicated by single-dotted arrows.

Each bank Bank has an independent input/output terminal I/O that is connected to a relevant PE in a one-to-one manner through a relevant controller Ctrl, and therefore, each PE or computing core corresponds to a multi-core that operates independently and independently accesses a memory. In order to transmit, from the controller Ctrl to the bank Bank, data transmitted and received between the PE and the bank Bank and the control signals CMD and ADDR received from an external host, since a number of controllers Ctrl corresponding to the number of PEs are required as an intermediary, there is a disadvantage of making a system complex and increasing a consumption of chip area.

A hybrid accelerator (HB accelerator) system in the related art maximizes bank-level parallelism by connecting each bank to its corresponding logic die in the HB method due to the low power and area overhead of HB. The latest AI models, such as large language models (LLMs), have large parameter sizes with simple operation structures, but hybrid accelerator systems with a plurality of small core structures in the related art are inefficient for the latest AI models.

The HB structure in the related art has a disadvantage in that a bottleneck phenomenon inevitably occurs in terms of signal transmission and reception by using an on-chip network or on-chip bus with a low bandwidth because banks accessible by each PE are limited. In other words, since each of a plurality of PEs constituting the logic chip 250 is not able to transmit and receive data to/from each other, there is a disadvantage in that the movement of data between the plurality of PEs needs to be performed using a separate process.

### SUMMARY

Various embodiments are directed to providing a hybrid bonding structure in which data is directly transmitted from a memory chip to a logic chip through a local transmission line during a read operation, data is transmitted from the logic chip to the memory chip through a global transmission line during a write operation, and a control signal is transmitted from the logic chip to the memory chip through the global transmission line, so that a plurality of banks can be simultaneously controlled and a plurality of PEs implemented in the logic chip operate as a single core.

Various embodiments are directed to providing a machine leaning hybrid accelerator including the hybrid bonding structure.

Technical problems to be solved in the present disclosure are not limited to the aforementioned technical problems and the other unmentioned technical problems will be clearly understood by those skilled in the art from the following description.

A hybrid bonding structure according to one aspect of the present disclosure may include: a first chip and a second chip connected in a hybrid bonding manner, wherein the first chip includes a bank, an input/output means, and a peripheral circuit, the second chip includes a PE group and a VPU/controller, the first chip and the second chip transmit and receive information through a global transmission line and a local transmission line, the local transmission line connects the bank and the PE group, and the global transmission line connects the peripheral circuit and the VPU/controller.

A hybrid bonding structure according to another aspect of the present disclosure may include: a memory chip and a logic chip connected in a hybrid bonding manner, wherein the memory chip includes a plurality of banks, a plurality of input/output means, and a peripheral circuit, the logic chip includes a plurality of PE groups and a VPU/controller, the memory chip and the logic chip transmit and receive information through a global transmission line and a local transmission line, the local transmission line connects relevant bank and PE group among the plurality of banks and the plurality of PE groups, and the global transmission line connects the peripheral circuit and the VPU/controller.

A machine leaning hybrid accelerator according to another aspect of the present disclosure may include the hybrid bonding structure.

Technical problems to be solved in the present disclosure are not limited to the aforementioned technical problems and the other unmentioned technical problems will be clearly understood by those skilled in the art from the following description.

In accordance with a hybrid bonding structure and a machine leaning accelerator including the hybrid bonding structure as described above according to the present disclosure, since all banks operate as a large single core, there is an advantage in that a simple operation structure and a parameter size are suitable for AI models, and a plurality of PEs are divided into sub-PE groups for use, and data applied to each PE group can be selected, so that a signal processing bandwidth is wide.

Effects achievable in the disclosure are not limited to the aforementioned effects and the other unmentioned effects will be clearly understood by those skilled in the art from the following description.

### BRIEF DESCRIPTION OF THE DRAWINGS

FIG. 1 illustrates a DRAM having a plurality of banks in the related art.

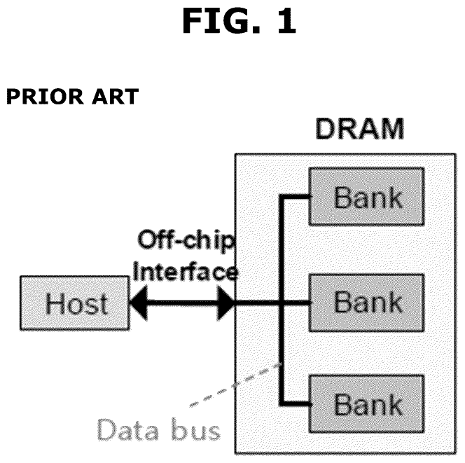

FIG. 2 illustrates an example of a hybrid bonding structure in the related art.

FIG. 3 illustrates a hybrid bonding structure according to the present disclosure.

FIG. 4 illustrates a first switch group constituting a logic chip and a first PE group corresponding to the first switch group.

FIG. 5 illustrates a last switch group constituting a logic chip and a last PE group corresponding to the last switch group.

FIG. 6 illustrates an embodiment of a peripheral circuit and a vector processing unit (VPU)/controller.

FIG. 7 illustrates a configuration of a hybrid bonding structure according to the present disclosure.

FIG. 8 illustrates a state where a memory chip and a logic chip are arranged vertically.

### DETAILED DESCRIPTION

In order to fully understand the present disclosure, advantages in operation of the present disclosure, and objects achieved by carrying out the present disclosure, the accompanying drawings for explaining illustrative examples of the present disclosure and the contents described with reference to the accompanying drawings may be referred to.

Hereinafter, the present disclosure is described in detail by describing preferred embodiments of the present disclosure with reference to the accompanying drawings. The same reference numerals among the reference numerals in each drawing indicate the same members.

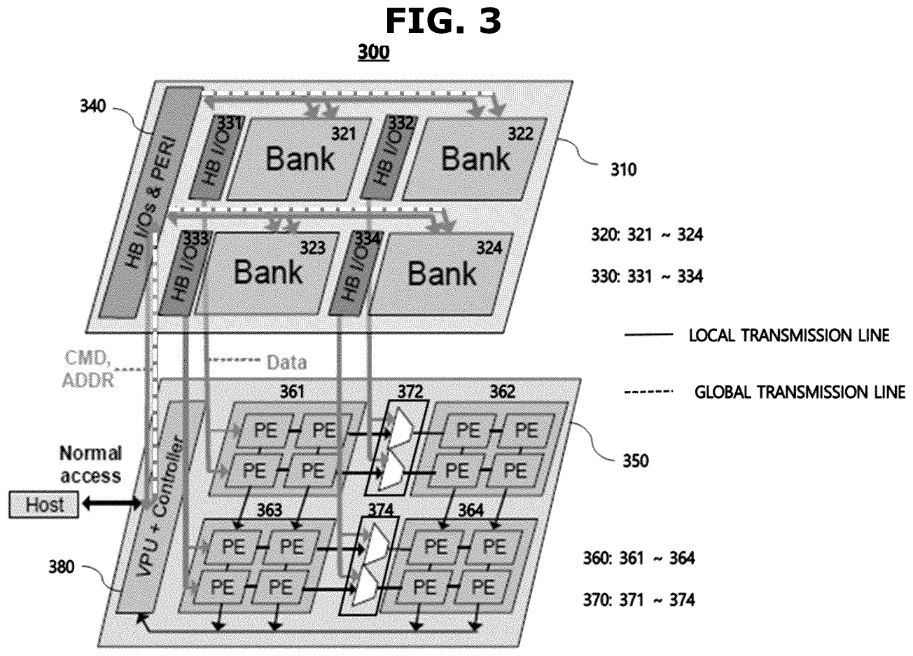

FIG. 3 illustrates an example of a hybrid bonding structure according to the present disclosure.

Referring to FIG. 3, a hybrid bonding structure 300 according to the present disclosure connects a memory chip 310 and a logic chip 350 in a hybrid bonding manner.

The memory chip 310 includes a plurality of banks 320 (Bank 321 to Bank 324), a plurality of input/output means 330 (HB I/O 331 to HB I/O 334), and a peripheral circuit 340.

The logic chip 350 includes a PE group 360 comprised of a plurality of PE arrays (PE Array 361 to PE Array 364) and a plurality of switch arrays 370 (switch array 372 and switch array 374) and a vector processing unit (VPU)/Controller 380 (labelled “VPU+Controller”).

The PE group 360 include the plurality of PE arrays 361 to 364 and the plurality of switch arrays 370 (switch array 372 and switch array 374), and each of the plurality of PE arrays 361 to 364 includes a plurality of processing elements (PEs) that together perform a multiply accumulating (MAC) operation.

The VPU/controller 380, is a processing block that includes a vector processing unit (VPU) and a controller.

Unlike the hybrid bonding structure 200 in the related art, the hybrid bonding structure 300 according to the present disclosure can minimize an area occupied by a layout by distinguishing local transmission lines respectively connecting the banks Bank 321 to 324 of the memory chip 310 and the plurality of PE arrays 361 to 364 of the logic chip 350 from global transmission lines connecting the peripheral circuit 340 of the memory chip 310 and the processing block 380 of the logic chip 350.

The local transmission line and the global transmission line refer to inter-chip transmission lines connecting the memory chip 310 and the logic chip 350, and do not refer to an internal transmission line of either of the memory chip 310 or the logic chip 350. That is, solid transmission lines or dotted transmission lines shown entirely inside the memory chip 310 or entirely inside the logic chip 350 are merely shown to facilitate understanding of signal transmission paths, and are not the local transmission lines or the global transmission lines.

The local transmission lines indicated by solid lines in FIG. 3 are respectively used to transmit data from the banks Bank 321 to 324 of the memory chip 310 to the PE group 360. That is, in a read mode of the memory, the data stored in a bank Bank is directly transmitted to the PE group 360 through a corresponding local transmission line. However, the data stored in the bank Bank is not directly transmitted to the PE group 360, but is transmitted via a corresponding one of the input/output means 330. FIG. 3 illustrates local transmission lines connected between the input/output means 330 and the PE group 360.

In a write mode of the memory, the VPU/controller 380 selects one of data supplied from the outside and data output from the plurality of PE arrays 361 to 364, and transmits the selected data to the plurality of banks 320 through the global transmission line.

In addition to transmitting data from the logic chip 350 to the memory chip 310 by using the global transmission line, the logic chip 350 performs a function of transmitting externally supplied control signals CMD and ADDR to the memory chip 310 by using the global transmission line.

In FIG. 3, the global transmission lines include two types of transmission lines (solid lines and dotted lines). The global transmission line indicated by the solid line is used to transmit data from the VPU/controller 380 of the logic chip 350 to the peripheral circuit 340 of the memory chip 310, and the global transmission line indicated by the dotted line is used for the VPU/controller 380 to transmit the control signals CMD and ADDR received from the host to the peripheral circuit 340.

In the present disclosure, data is transmitted during a read operation through different transmission lines than those used to transmit data during a write operation, thereby expanding a signal transmission bandwidth.

Each bank Bank 321 to 324 records (or stores) data received via the peripheral circuit 340, in response to information included in the control signals CMD and ADDR received via the peripheral circuit 340.

In the above description, the peripheral circuit 340 refers to a region where a plurality of input/output interfaces I/O required to receive global transmission lines and transmission lines for transmitting data and the control signals CMD and ADDR received through the input/output interfaces I/O to corresponding banks Bank are formed.

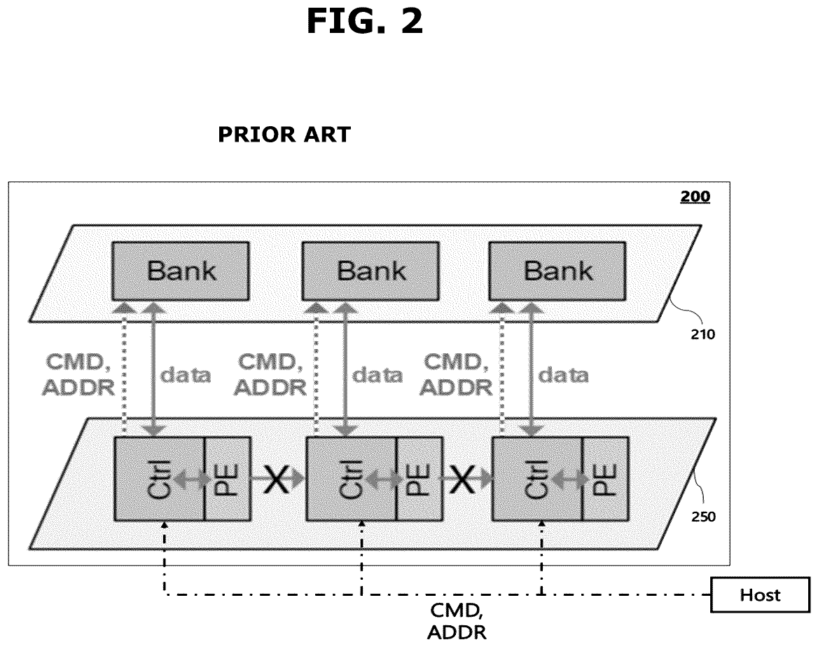

Compared to the hybrid bonding structure 200 in the related art illustrated in FIG. 2, the hybrid bonding structure 300 according to the present disclosure illustrated in FIG. 3 includes the following differences.

First, there are the following differences in the configuration of each chip.

### Difference 1: Target of Transmission and Reception of Data and Control Signals

In the hybrid bonding structure 200 in the related art, each bank Bank and the corresponding controller Ctrl directly transmit and receive the data and the control signals CMD and ADDR. In contrast, the peripheral circuit 340 included in the memory chip 310 of the hybrid bonding structure 300 according to the present disclosure transmits the control signals CMD and ADDR and the data received through the global transmission line to the plurality of banks Bank connected to respective buses (dotted lines & solid lines). Data transmitted from the logic chip 350 to the memory chip 310 through the solid global transmission line includes not only data transmitted from each PE to the VPU/controller but also data supplied from the outside (such as from a Host) to the VPU/controller

### Difference 2: Information Transmitted and Received Through Transmission Lines

The hybrid bonding structure 200 in the related art illustrated in FIG. 2 and the hybrid bonding structure 300 according to the present disclosure illustrated in FIG. 3 can be said to be similar in that they commonly use transmission lines for data and transmission lines for the control signals CMD and ADDR, but they differ in the number of transmission lines and whether a specific transmission line transmits and receives data or only transmits data. For example, all of the transmission lines used for data in the hybrid bonding structure 200 are bidirectional; in contrast, at least some of the transmission lines used for data in the hybrid bonding structure 300 are unidirectional.

### Difference 3: Number of Transmission Lines

The hybrid bonding structure 200 in the related art requires as many transmission lines as the number of banks and PEs, and it can be seen that the structure 200 in the related art illustrated in FIG. 2 requires a total of six transmission lines because three banks and three PEs are installed. Each transmission line illustrated in FIG. 2 represents not one transmission line but a transmission line group including a plurality of transmission lines, but is illustrated as one transmission line in order to simplify the drawing. On the other hand, the hybrid bonding structure 300 according to the present disclosure requires a local transmission line (solid line) connecting the bank Bank and the PE and two global transmission lines (dotted line & solid line) connecting the VPU/controller and the peripheral circuit 340, and referring to FIG. 3, it can be seen that a total of five transmission lines (each representing a group of transmission lines) are required.

Referring to the embodiments illustrated in FIGS. 2 and 3, since the hybrid bonding structure 200 in the related art requires a total of six transmission lines in order to connect the memory chip 210 and the logic chip 250 and the hybrid bonding structure 300 according to the present disclosure requires a total of five transmission lines (i.e. four local and one global) in order to connect the memory chip 310 and the logic chip 350, the difference in the number of transmission lines is one. Such a comparison result is because the number of banks was set to three in the hybrid bonding structure in the related art for convenience of explanation, and it can be easily expected that the difference in the number of transmission lines used in the hybrid bonding structure in the related art and the hybrid bonding structure according to the present disclosure increases as the number of banks increases. For example, when the number of banks is four in both cases, a hybrid bonding structure in the related art would have 8 (groups of) transmission lines, while a hybrid bonding structure according to an embodiment of this disclosure would have the 5 (groups of) transmission lines shown in FIG. 3.

In addition to the difference in the number of transmission lines as described above, there is also a difference in that the transmission lines used are distinguished according to the data transmission direction.

In FIGS. 2 and 3, the data transmission direction is the direction of the arrows.

Referring to FIG. 2, in the hybrid bonding structure 200 in the related art, the control signals CMD and ADDR and data are transmitted or transmitted/received in pairs between a pair comprising a bank Bank and a controller Ctrl, but referring to FIG. 3, in the hybrid bonding structure 300 according to the present disclosure, data is transmitted in one direction through the local transmission line between the bank Bank and the PE, and the control signals CMD and ADDR are transmitted in one direction and data is transmitted in two directions between the VPU/controller 380 and the peripheral circuit 340, which is different.

### Difference 4: Use of Intermediate Buffer

Unlike the hybrid bonding structure 200 in the related art, the local transmission line and the global transmission line allow data to be directly transmitted to the PE without an intermediate buffer or a controller and transmit the control signals CMD and ADDR and data in only one direction, and exceptionally, the global transmission line transmits data in both directions.

By using the bus lines inside the peripheral circuit 340 and the memory chip 310, the data and the control signals CMD and ADDR can be transmitted to the plurality of banks simultaneously.

The hybrid bonding structure 300 according to the present disclosure can be designed to include a plurality of channels, and FIG. 3 illustrates one embodiment of the hybrid bonding structure 300 including two channels.

In FIG. 3, a first channel includes two banks 321 and 322 commonly connected to one bus in the memory chip 310 and two PE array 361 and 362 in the logic chip 350. A second channel includes two banks 323 and 324 commonly connected to another bus in the memory chip 310 and two PE groups 363 and 364 in the logic chip 350.

Each PE group is connected to a corresponding switch group, and each switch group can select one of data output from a preceding PE group and data read from a relevant bank, and can transmit the selected data to a subsequent PE group.

In FIG. 3, the second PE group 362 can select/receive one of data output from the preceding first PE group 361 and data read from a relevant bank 322 by using the second switch group 372 installed in the front stage.

FIG. 3 illustrates that the first PE group 361 receives only data read from a relevant bank 321 without the first switch group 371. However, this is merely one embodiment, and an embodiment in which the first PE group 361 includes the first switch group 371 is also possible.

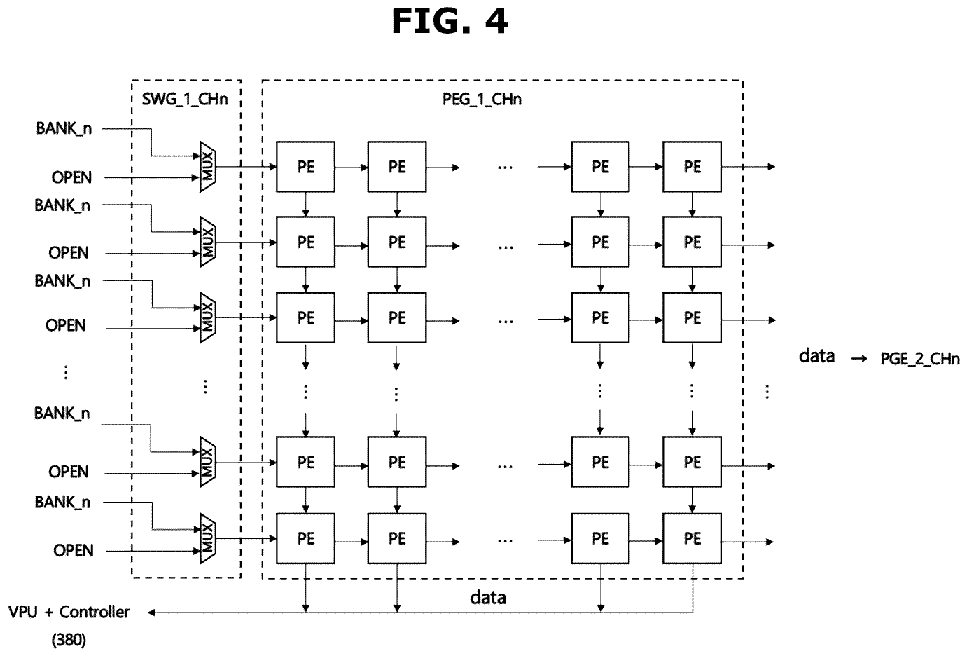

FIG. 4 illustrates an example of a first switch group SWG_1_CHn implemented in a logic chip and a first PE group PEG_1_CHn corresponding to the first switch group SWG_1_CHn. The first switch group SWG_1_CHn may correspond to one of the switch groups 372 and 374 of FIG. 4, and the first PE group PEG_1_CHn may correspond to one of the PE groups 362 and 364 of FIG. 3.

FIG. 4 illustrates a first switch group SWG_1_CHn and a first PE group PEG_1_CHn included in an arbitrary channel n (CHn, where n is a natural number), and in the first PE group PEG_1_CHn, a plurality of PEs are preferably arranged to have a systolic array structure.

As illustrated in FIG. 4, the first switch group SWG_1_CHn includes a plurality of multiplexers MUX and at least five multiplexers MUX are illustrated in a vertical direction, and the arrangement and number of the multiplexers can be selected in units of signal processing.

When the switch group SWG_1_CHn illustrated in FIG. 4 is a first switch group in a channel, a first input terminal of each multiplexer MUX included in the switch group SWG_1_CHn receives data from a corresponding bank BANK_n, and a second input terminal of each multiplexer MUX may be connected to the VPU/controller 380. Accordingly, when the multiplexer MUX selects only data from a corresponding bank through one terminal thereof, it can be seen that a structure in which the first switch group SWG_1_CHn is connected to the first PE group PEG_1_CHn is possible.

FIG. 3 illustrates an embodiment in which the first switch group (such as switch group SWG_1_CHn of FIG. 4) is not illustrated in front of the first PE group 361. However, considering the etching tolerance of an element or a transmission line to be implemented in a semiconductor process, an embodiment including the first switch group SWG_1_CHn and the first PE group PEG_1_CHn as a pair as illustrated in FIG. 4 may be preferable.

The embodiment illustrated in FIG. 4 may be distinguished from an embodiment in which switch group is not connected to the first PE group 361 illustrated in FIG. 4.

The first PE group PEG_1_CHn illustrated in FIG. 4 includes a plurality of PEs arranged in two dimensions, input data is transmitted to neighboring PEs arranged in a horizontal direction, and output data is output to PEs arranged in a vertical direction.

In FIG. 4, data output from the plurality of PEs located at the bottom in the vertical direction is transmitted to the VPU/controller 380, and data output from PEs located at the rightmost in the horizontal direction is transmitted to the second PE array group PEG_2_CHn (in embodiments, through a switch group such as the switch group 372 of FIG. 3).

In FIG. 4 described above, the illustrated switch group and PE group are assumed to be the first switch group/PE group pairs in each arbitrary channel, but can also be applied to the second through last switch group/PE group pairs in an arbitrary channel.

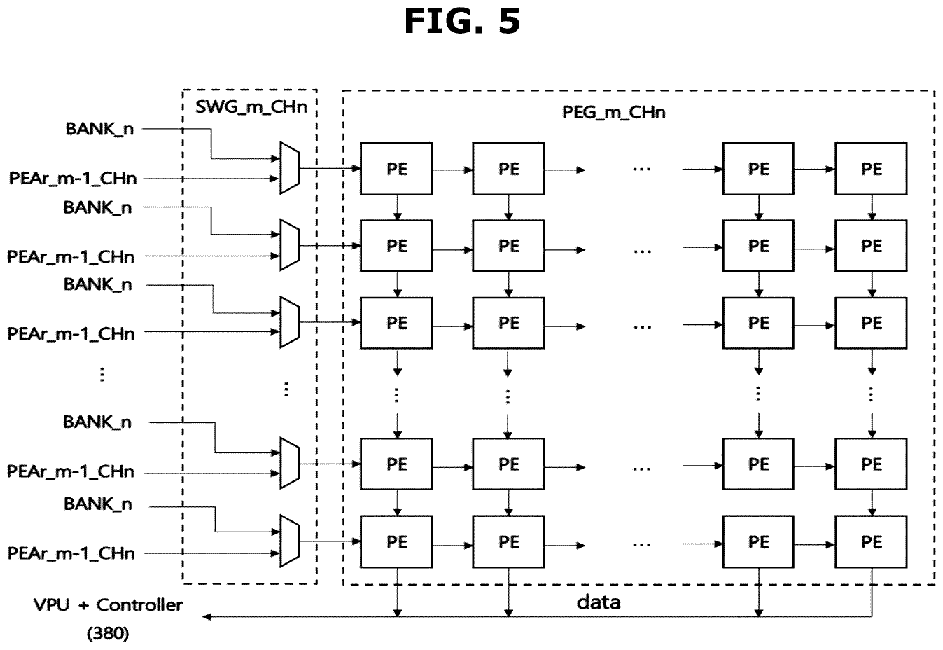

FIG. 5 illustrates an example of a last switch group SWG_m_CHn included in a logic chip and a last PE group PEG_m_CHn corresponding to the last switch group.

Referring to FIG. 5, the configuration of an m^{th} (m is a natural number equal to or greater than 2) switch group SW_m_CHn and an m^{th} PE group PEG_m_CHn in an arbitrary n^{th} channel CHn is the same as the first switch group SWG_1_CHn and the first PE group PEG_1_CHn included in the arbitrary n channel CHn (n is a natural number) illustrated in FIG. 5.

However, there is a difference in that in each multiplexer MUX included in the m^{th} switch group SW_m_CHn, one terminal receives data read from a relevant bank BANK_n and the other terminal receives data output from a previous PE group PEG_m-1_n.

It can be seen that the first PE group PEG_1_CHn of the arbitrary n channel can receive only data read from a corresponding bank (or, in some embodiments from the VPU/controller 380), but the second and subsequent PE groups PEG_2_n to PEG_m_n can selectively receive data from a respective previous PE group or the respective corresponding bank.

Assuming that m is the last of the channels, data output from a plurality of PEs located at the bottom of the PE group PEG_m_CHnd illustrated in FIG. 5 is transmitted to the VPU/controller 380, but there is no PE group to which data output from the PE located at the bottom in the horizontal direction is transmitted.

Referring to FIG. 4, the first switch group SWG_1_CHn includes a plurality of multiplexers MUX, and at least five multiplexers MUX are illustrated in the vertical direction. The arrangement and number of the multiplexers can be selected/changed in units appropriate for signal processing, and for example, it is possible for the first switch group SWG_1_CHn to include sixteen multiplexers MUX in the vertical direction. The first PE group PEG_1_CHn includes at least four PEs in the vertical direction and at least four PEs in the horizontal direction, but the arrangement and number of the PEs can be selected/changed in units appropriate for signal processing; for example, it is possible for the first PE group PEG_1_CHn to include eight PEs in the horizontal direction and sixteen Pes in the vertical direction

The above description about FIG. 4 can be equally applied to the switch group illustrated in FIG. 5 and the PE group corresponding to the switch group.

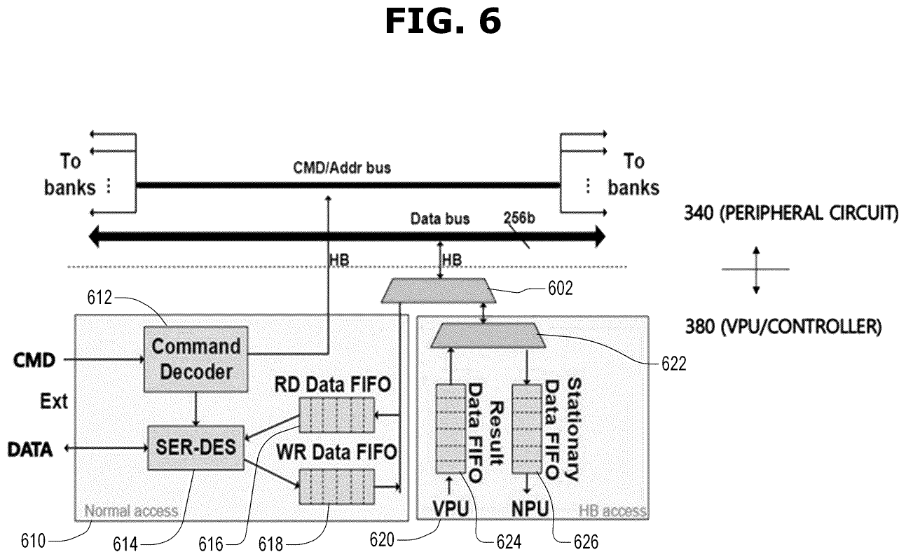

FIG. 6 illustrates an embodiment of a peripheral circuit 340 and a VPU/controller 380.

The upper part of FIG. 6 indicates the peripheral circuit 340 and the lower part thereof indicates a part of the VPU/controller 380. Referring to FIG. 6, the VPU/controller 380 performs a normal access using normal access datapath 610 and an HB access according to the present disclosure using an HB access datapath 620.

In the case of the normal access, a command CMD and data are input from the outside. The command CMD input from the outside can be transmitted to the peripheral circuit 340 of the memory chip 310 through a command decoder 612 and the global transmission line, and the data DATA can be transmitted to the peripheral circuit 340 through the global transmission line via a Serializer/Deserializer (SER-DES) 614 and a Write (WR) Data First-In-First-Out (FIFO) queue 618. Data received through the peripheral circuit 340 can be transmitted to the outside through a shift-register-type Read (RD) Data FIFO queue 616 and the SER-DES 614. In embodiments, a selector circuit 602 couples the normal access datapath 610 to the HB data bus during the normal access.

In the case of the access according to the present disclosure, data received from the peripheral circuit 340 can be transmitted to a processor unit neural processing unit (NPU) (such as may be implemented using some or all of the PE Groups of the logic chip 350) through a Stationary Data FIFO queue 626, and data output from the processor unit VPU of the VPU/Controller 380 is transmitted to the peripheral circuit 340 through the global transmission line via a shift-register-type Result Data FIFO queue 624. A steering circuit 622 routes data received from the peripheral circuit 340 to the Stationary Data FIFO queue 626 and routes data from the Result Data FIFO queue 624 to the peripheral circuit 340. In embodiments, the selector circuit 602 couples the HB access datapath 620 to the HB data bus during the normal access.

The peripheral circuit 340 is provided with a control signal bus CMD/Addr bus and a data bus Data bus each connected to a plurality of banks Bank such as shown in FIG. 3. The control signal bus CMD/Addr bus serves as a passage for transmitting the control signals CMD and ADDR received from the VPU/controller 380 to a corresponding bank Bank, and the data bus Data bus serves as a passage for transmitting and receiving data between the plurality of banks Bank and the VPU/controller 380.

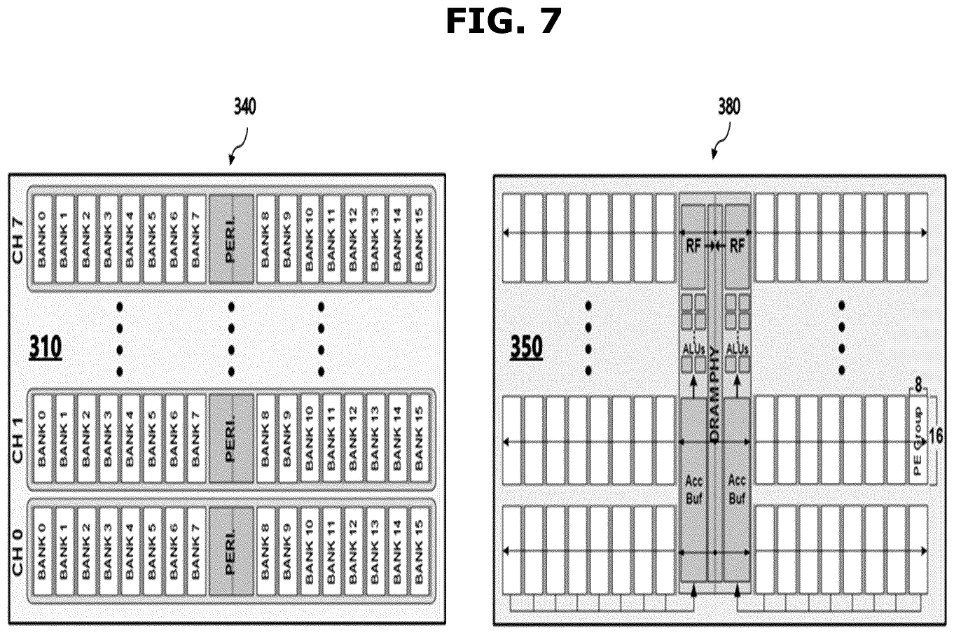

FIG. 7 illustrates an example of the configuration of the hybrid bonding structure according to the present disclosure.

Referring to FIG. 7, it is assumed that the hybrid bonding structure according to the present disclosure is a hybrid bonding of the memory chip 310 and the logic chip 350 and includes 8 channels CH 0 to CH 7.

The memory chip 310 illustrated on the left includes 16 banks BANK 0 to BANK 15 per channel, and the peripheral circuit 340 (PERI) is installed in the central between an eighth bank BANK 7 and a ninth bank BANK 8 constituting each channel.

The logic chip 350 illustrated on the right includes 16 PE groups PE Groups per channel, and the VPU/controller 380 is installed in the central area between an eighth PE group and a ninth PE group of the PE groups constituting each channel.

A plurality of PE groups arranged in series on the same channel can transmit data in one direction. Since the VPU/controller 380 is installed in the center, input data for the 8 PE groups on the left side of the center is transmitted from the center to the left, and input data for the 8 PE groups on the right side of the center is transmitted from the center to the right. In an embodiment, each PE group has 8 PEs arranged in the horizontal direction and 16 PEs arranged in the vertical direction.

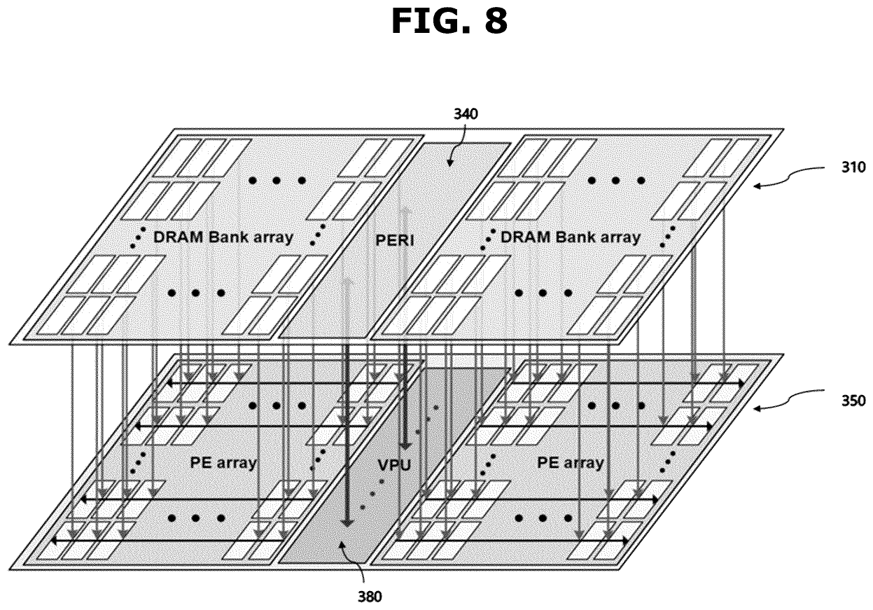

FIG. 8 illustrates a state where a memory chip 310 and a logic chip 350 are arranged vertically according to an embodiment.

Referring to FIG. 8, it can be seen that the positions of the peripheral circuit 340 formed in the center of the memory chip 310 and the VPU/controller 380 formed in the center of the logic chip 350 are precisely aligned. In addition, a plurality of bidirectional vertical lines (thick vertical lines) connecting the peripheral circuit 340 and the VPU/controller 380 are global transmission lines, and a plurality of vertical lines (thin vertical lines) connecting a plurality of banks constituting the DRAM Bank array of the memory chip 310 and each PE constituting the PE group of the logic chip 350 are local transmission lines.

Referring to the above description, the hybrid bonding structure 300 according to the present disclosure can transmit the control signals CMD and ADDR by using a smaller number of local transmission lines and global transmission lines than the number of transmission lines used in hybrid bonding structures of the related arts.

In particular, the present disclosure proposes to additionally install a VPU capable of performing deep neural network (DNN) post-processing in the logic chip 350, and since the VPU can perform DNN post-processing, it can gather data output from the PE array, perform a post-processing process on the gathered data, and store the processed data in the banks of the memory chip 310 through the global transmission line. The post-processing process may include normalization, softmax, activation, or a combination thereof.

The hybrid bonding structure according to the present disclosure can divide the entire PE into a plurality of PE groups and select data to be transmitted to each of the plurality of PE groups, thereby reducing a consumption area or power consumption, and in particular, since all banks can operate as one large core, it can be said to have optimal conditions for application to a machine learning accelerator.

Although the technical spirit of the present disclosure has been described together with the accompanying drawings, this is an illustrative example of a preferred embodiment of the present disclosure, but does not limit the present disclosure. In addition, it is clear that various modifications and imitations can be made by anyone skilled in the art to which the present disclosure belongs without departing from the scope of the technical spirit of the present disclosure.

What is claimed is:

1. A hybrid bonding structure comprising:
a first chip comprising a bank, an input/output means, and a peripheral circuit;
a second chip comprises a PE group and controller block;
a global transmission line connecting the first chip and the second chip in a hybrid bonding manner; and
a local transmission line connecting the first chip and the second chip in the hybrid bonding manner,
wherein first information is communicated between the bank and the PE group using the local transmission line, and
wherein second information is communicated between the peripheral circuit and the controller block using the global transmission line.

2. The hybrid bonding structure of claim 1, wherein the first information includes data stored in the bank that is transmitted to the PE group through the input/output means, and
wherein the second information includes data to be stored in the bank that is transmitted to the bank through the controller block.

3. The hybrid bonding structure of claim 2, wherein the data to be stored in the bank is selected from data supplied from outside of the second chip and data generated in the PE group.

4. The hybrid bonding structure of claim 1, wherein the peripheral circuit comprises:
an input/output interface configured to communicate using the global transmission line; and
a region where a transmission line for transmitting data and a control signal received through the input/output interface to the bank is formed.

5. The hybrid bonding structure of claim 1, wherein the PE group comprises:
a PE array in which a plurality of PEs configured to perform a multiply accumulate operation and arranged in a systolic array structure; and
a switch array comprising a plurality of switches configured to select one of two types of data and transmit the selected data to the PE array,
wherein the one of the two types of data is output from the bank.

6. The hybrid bonding structure of claim 1, wherein the controller block comprises a vector processing unit (VPU) and a controller circuit.

7. A hybrid bonding structure comprising:
a memory chip comprising a plurality of banks, a plurality of input/output means, and a peripheral circuit;
a logic chip comprises a plurality of PE groups and a controller block;
a local transmission line connected between the memory chip and the logic chip in a hybrid bonding manner and configured to respectively communicate first information between the plurality of banks of the memory chip and the plurality of PE groups of the logic chip; and
a global transmission line connected between the memory chip and the logic chip in the hybrid bonding manner and configured to communicate second information between the peripheral circuit of the memory chip and the VPU/controller of the logic chip.

8. The hybrid bonding structure of claim 7, wherein in a read mode, the first information includes data stored in a bank of the plurality of banks that is transmitted to a corresponding PE group of the plurality of PE groups through an input/output means corresponding to the bank, and
in a write mode, the second information includes data selected from data transmitted from the corresponding PE group and data supplied from an outside of the logic chip and that is transmitted to the bank through the controller block.

9. The hybrid bonding structure of claim 7, wherein the peripheral circuit comprises:
a plurality of input/output interfaces configured to communicate with the global transmission line; and
a region where a transmission line for transmitting data and a control signal received through an input/output interface of the plurality of input/output interfaces to a corresponding bank of the plurality of banks is formed.

10. The hybrid bonding structure of claim 7, wherein a first PE group of the plurality of PE groups comprises:
a PE array in which a plurality of PEs configured to perform a multiply accumulate operation are arranged in a systolic array structure; and
a switch array comprising a plurality of switches configured to select one of two types of data and transmit the selected data to the PE array,
wherein the two types of data are data output from a corresponding bank of the plurality of banks and data output from a PE array of a second PE group of the plurality of PE groups.

11. The hybrid bonding structure of claim 7, wherein the controller block comprises a vector processing unit (VPU) and a controller circuit.

12. The hybrid bonding structure of claim 11, wherein the controller block further comprises a command decoder, a serializer-deserializer (SER-DES) circuit, a Read Data FIFO queue for reading, a Write Data FIFO queue for writing, a Stationary Data FIFO queue for reading, and a Result Data FIFO queue for writing, and
in a case of a normal access, a command supplied from an outside of the logic chip is transmitted, by the controller block in the second information, to the peripheral circuit through the command decoder,
data supplied from the outside of the logic chip is transmitted, by the controller block in the second information, to the peripheral circuit via the SER-DES circuit and the Write Data FIFO queue, and
data received, by the controller block in the second information, through the peripheral circuit is transmitted to the outside of the logic chip via the Read Data FIFO queue and the SER-DES circuit.

13. The hybrid bonding structure of claim 12, wherein in a case of a unique access, data received, by the controller block in the second information, from the peripheral circuit is transmitted to the VPU via the Stationary Data FIFO queue, and
data output from the VPU is transmitted, by the controller block in the second information, to the peripheral circuit via the Result Data FIFO queue

14. A machine leaning accelerator comprising the hybrid bonding structure of claim 7.
